(19) United States
(12) Patent Application Publication
(10) Pub. No.: US 2006/0226508 A1
(43) Pub. Date: Oct. 12, 2006

(54) SEMICONDUCTOR DEVICE HAVING PATTERNS FOR PROTECTING FUSES AND METHOD OF FABRICATING THE SEMICONDUCTOR DEVICE

(76) Inventors: Su-Jin PARK, Seoul (KR); Sung-Hoon KIM, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/279,090

(22) Filed: Apr. 7, 2006

(30) Foreign Application Priority Data
Apr. 8, 2005 (KR) 10-2005-29598

(51) Int. Cl. H01L 29/00

(52) U.S. Cl. 257/529

(57) ABSTRACT

A semiconductor device having patterns for protecting fuses is provided. The semiconductor device comprises a plurality of fuses formed on a semiconductor substrate, and a pattern covering a region of the semiconductor device where the fuses are not to be cut. The patterns formed on the semiconductor device protect the fuses in the region not to be cut from fragments generated during a fuse cutting process in adjacent regions where the fuses may be cut. By protecting the fuses in this region, short circuits between the fuses caused by the fuse fragments can be prevented.

### CROSS-REFERENCE TO RELATED PATENT APPLICATION

This application claims the benefit of Korean Patent Application No. 10-2005-29598, filed on Apr. 8, 2005, in the Korean Intellectual Property Office, the disclosure of which is incorporated herein in its entirety by reference.

### BACKGROUND

1. Field of the Invention

The present invention relates to a semiconductor device, and more particularly, to a semiconductor device having patterns for protecting fuses.

2. Description of the Related Art

When a defect occurs in one of the memory cells of a semiconductor device, the semiconductor device cannot perform its functions normally. Further, if the entire semiconductor device fails to operate due to a defect in one of the memory cell, the manufacturing yield becomes low. To solve this problem, a semiconductor device generally includes redundant cells to replace defective cells. In this instance, when a defect occurs in a memory cell, a redundant cell is used to replace the defective cell, thereby preventing the failure of the semiconductor device and improving the manufacturing yield.

In general, a fuse is used to separate a defective cell from the rest of the semiconductor device. If a defective cell is found by testing the semiconductor device, the fuse connected to the defective cell is cut using a laser beam, so that the defective cell is separated from the semiconductor device. However, during the fuse cutting process, metal fragments from the cut fuse may be generated, and the metal fragments may interfere with adjacent fuses that are not cut. Thus, the metal fragments may cause an electric short circuit between the cut fuse to be cut and an adjacent uncut fuse, which may cause the failure of the semiconductor device.

FIG. 1 is a plan view illustrating an arrangement of fuses in a conventional semiconductor device 100. Referring to FIG. 1, the conventional semiconductor device 100 includes an electrode 101 connected with fuses 105, a metal-3 coverage region 130, and a metal-2 coverage region 135. Specifically, FIG. 1 shows a region 120 where fuses may be cut and regions 110 and 140 where fuses are generally not cut.

FIG. 2 is a cross-sectional view taken along line A-A′ of FIG. 1. FIG. 2 discloses a metal-2 region 211, a contact 212, a metal-3 region 213, an interlayer insulating layer 214, an insulation layer 240, and a fuse dam 210. The fuse dam 210 is formed to protect an external circuit from fragments generated when cutting a fuse. Also, FIG. 2 shows a region 120 where fuses are cut and a region 110 where fuses are not cut.

The fuses are arranged in a zigzag pattern as shown in FIG. 1, in order to reduce the likelihood of a short circuit between the fuse to be cut and an adjacent fuse during a cutting process. That is, the fuses are arranged in a pattern such that adjacent fuses in the regions 110 and 140, where the fuses are not generally cut, are spaced relatively close to one another in comparison to the adjacent fuses in the region 120, where the fuses are generally cut.

In other words, when a cell is defective in the conventional semiconductor device 100 and the fuse connected to the defective cell must be cut, the fuse is generally not cut in the region 140 where fuses are spaced relatively close to one another, but rather in the region 120 where fuses are spaced further apart from one another. Thus, it is possible to reduce the possibility of damaging an uncut fuse by fragments generated during the cutting process of an adjacent fuse connected to the defective cell.

However, although the fuses arranged in the zigzag pattern have a lower occurrence of creating short circuits during a fuse-cutting process, it is difficult to completely prevent the fragments generated during the cutting process from affecting the surrounding fuses that are to remain intact. For example, as shown in FIG. 2, fragments of a fuse generated during a cutting process in the region 120 may interfere with the fuses in the adjacent region 110, where the fuses are grouped more closely and are generally not cut. This interference, in turn, may cause a short circuit between the region 120 and the region 110 or between the fuses located in region 110.

### SUMMARY

Embodiments of the present invention provide a semiconductor device having pattern units for protecting fuses and a method of fabricating the semiconductor device have the fuse-protecting pattern units.

According to an embodiment of the present invention, a semiconductor device includes a plurality of fuses formed over a semiconductor substrate, and a pattern unit covering the upper part of a region not to be cut, among the plurality of fuses.

### BRIEF DESCRIPTION OF THE DRAWINGS

The above and other features and advantages of the present invention will become more apparent by describing in detail exemplary embodiments thereof with reference to the attached drawings in which:

FIG. 1 is a plan view illustrating an arrangement of fuses in a conventional semiconductor device;

FIG. 2 is a cross-sectional view taken along line A-A′ of FIG. 1;

FIG. 3 is a plan view illustrating a semiconductor device having patterns for protecting fuses in accordance with an embodiment of the present invention; and

FIG. 4 is a cross-sectional view taken along line B-B′ of FIG. 3.

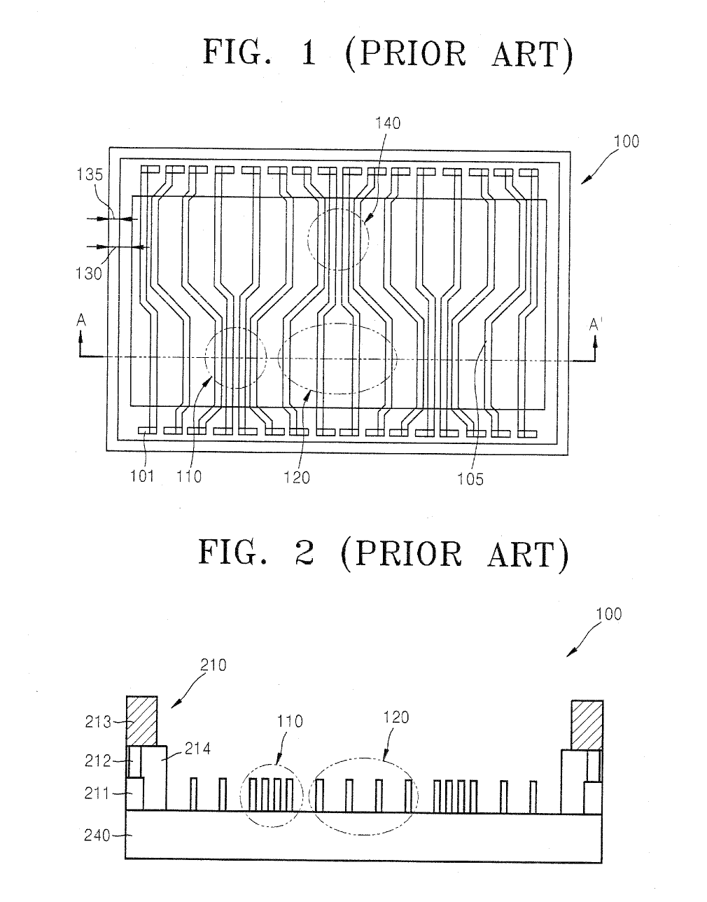

### DETAILED DESCRIPTION

The present invention will now be described more fully hereinafter with reference to the accompanying drawings, in which embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. Like numbers refer to like elements throughout the specification.

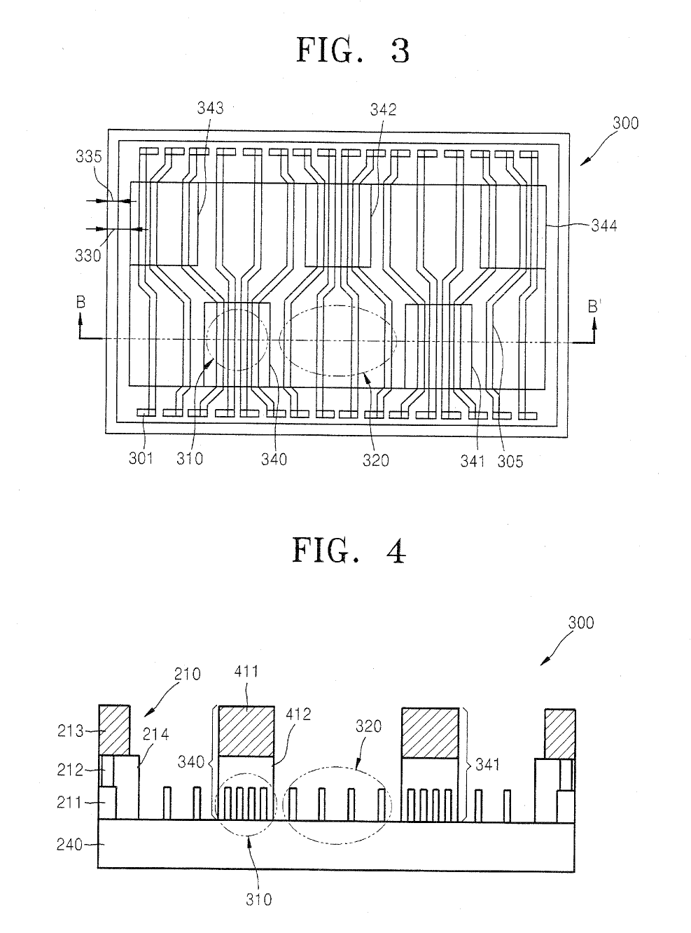

FIG. 3 is a plan view illustrating a semiconductor device 300 according to an embodiment of the present invention. Referring to FIG. 3, the semiconductor device 300 includes electrodes 301 connected with fuses 305, a metal-3 coverage region 330, a metal-2 coverage region 335, and pattern units 340, 341, 342, 343, and 344 covering the upper part of a region 310 where the fuses are generally not cut. For convenience of explanation, only a region 320, where fuses are generally cut, and a region 310, where fuses are generally not cut, are shown in FIG. 3. However, the semiconductor device 300 may have other regions not shown in FIG. 3.

FIG. 4 is a cross-sectional view taken along line B-B′ of FIG. 3, FIG. 4 discloses pattern units 340 and 341, a fuse dam 210, and an insulation layer 240, which are formed on a semiconductor substrate (not illustrated). The pattern units 340 and 341 include an interlayer insulating layer 412 covering the upper part of a fuse, and a conductive pattern, e.g., a metal pattern 411 covering the upper part of the interlayer insulating layer, respectively. The fuse dam 210 includes a metal-2 region 211, a contact 212, a metal-3 region 213, and an interlayer insulating layer 214. Also, a region 320, where fuses are generally cut, and a region 310, where fuses are generally not cut, are shown in FIG. 4.

Metal-1, metal-2 and metal-3 are conductors which are formed in the layers above the semiconductor substrate. Metal-1, metal-2 and metal-3 connect substances on the semiconductor substrate to outside electrically. Metal-1 is formed in the layer above the semiconductor substrate. And metal-2 is formed in the layer above the layer in which metal-1 is formed. And metal-3 is formed in the layer above the layer in which metal-2 is formed.

Referring to FIGS. 3 and 4, the metal pattern 411 and the interlayer insulating layer 412 cover the upper part of the region 310, where fuses formed on the insulation layer 240 are generally not cut. However, in this embodiment, the region 320, where fuses may be cut, is not covered. In other embodiments, however, the region 320 may be covered with a material that would still allow the fuses in the region 320 to be cut if necessary. In this embodiment, the metal pattern 411 may be formed of metal-3, and the fuses 305 may be formed of metal-2.

The metal pattern 411 and the interlayer insulating layer 412 are formed in the process of fabricating the semiconductor device. After the insulation layer 240 is formed, metal-2 may be formed on the insulation layer 240. Then, the fuses 305 and a metal-2 region 211 of the fuse dam 210 may be formed by etching the metal-2 layer. Next, an insulating material is formed to enclose the fuses 305 and the metal-2 region 211 of the fuse dam 210. The interlayer insulating layer 214 of the fuse dam 210 and the interlayer insulating layer 412 of the pattern unit 340 may be formed by etching the insulating material. Metal-3 is then formed on the insulating material, and a metal-3 region 213 of the fuse dam 210 and a metal pattern 411 of the pattern unit 340 may be formed by etching the metal-3 layer.

Since both the fuses 305 and the metal-2 region 211 of the fuse dam 210 are formed of metal-2, they may be formed in the same process. The interlayer insulating layer 412 of the upper part of the region 310 and the interlayer insulating layer 214 of the fuse dam 210 may also be formed in the same process. Also, the metal pattern 411 of the upper part of the region 310 and the metal-3 region 213 of the fuse dam 210 may be formed in the same process.

Therefore in the embodiment described above, even if fragments are generated during a fuse-cutting process, where a specific fuse in the semiconductor device 300 is cut to isolate a defect in part of the semiconductor device, adjacent regions, where fuses are more tightly grouped because of space considerations, can be protected against short circuits by the metal pattern 411 and the interlayer insulating layer 412. In other words, embodiments of the present invention can prevent short circuits in semiconductor device regions, where fuse cutting does not generally take place, with much more certainty in comparison to conventional devices. While the present invention has been particularly shown and described with reference to exemplary embodiments thereof, it will be understood by those of ordinary skill in the art that various changes in forth and details may be made therein without departing from the spirit and scope of the present invention as defined by the following claims.

What is claimed is:

1. A semiconductor device comprising:
a plurality of fuses over an insulating layer formed on a semiconductor substrate; and
a pattern unit covering a first portion of the plurality of fuses, wherein the covered first portion of the plurality of fuses are not to be cut.

2. The semiconductor device of claim 1, wherein the pattern unit comprises:
an interlayer insulating layer enclosing the covered first portion of the plurality of fuses; and
a conductive pattern formed on the interlayer insulating layer, the conductive pattern overlying the covered first portion of the plurality of fuses.

3. The semiconductor device of claim 2, wherein the fuses are formed of metal-2 and the conductive pattern is formed of metal-3.

4. The semiconductor device of claim 1, further comprising a second portion of the plurality of fuses that may be cut, wherein fuses in the first portion of the plurality of fuses are spaced closer to one another than fuses in the second portion of the plurality of fuses.

5. The semiconductor device of claim 4, wherein the first portion and the second portion are adjacent.

6. A method of fabricating a semiconductor device to prevent a fuse short circuit during a fuse-cutting process, the method comprising:
forming a plurality of fuses over an insulating layer formed on a semiconductor substrate;
forming an interlayer insulating layer over a first portion of the plurality of fuses; and
forming a conductive pattern on the interlayer insulating layer, the conductive pattern overlying the covered first portion of the plurality of fuses.

7. The method of claim 6, wherein the first portion of the plurality of fuses are not to be cut.

8. The method of claim 7, wherein the fuses are formed of metal-2, and the conductive pattern is formed of metal-3.

9. The method of claim 7, wherein fuses in the second portion of the plurality of fuses are spaced further apart from one another than fuses in the first portion of the plurality of fuses, wherein the second portion of the plurality of fuses are to be cut.

10. A semiconductor device comprising:
an insulting layer formed over a semiconductor substrate;
a fuse dam formed along at least one edge of the insulating layer, the fuse dam including a first insulating portion, a first conductive portion, and a second conductive portion;
a plurality of fuses formed on the insulating layer, wherein the fuses are patterned to form a first region where the fuses are not cut and a second region where the fuses may be cut;
an interlayer insulting layer formed to cover the first region of fuses; and
a conductive pattern formed on the interlayer insulating layer, wherein a least a portion of the conductive pattern is formed to be over the first region of fuses.

11. The semiconductor device of claim 10, wherein the first region and the second region are adjacent.

12. The semiconductor device of claim 10, wherein the fuses in the first region are spaced closer together than the fuses in the second region.

13. The semiconductor device of claim 10, wherein the first metal portion of the fuse dam is formed of the same material as the plurality of fuses, the second metal portion of the fuse dam is formed of the same material as the conductive pattern, and the insulating portion of the fuse dam is formed of the same material as the interlayer insulating layer.
